(19) United States
(12) Patent Application Publication
(10) Pub. No.: US 2007/0223296 A1
(43) Pub. Date: Sep. 27, 2007

(54) Bitline isolation control to reduce leakage current in memory device

(76) Inventors: Christopher Miller, Underhill, VT (US); Andre Sturm, Essex Junction, VT (US); Wolfgang Hokenmaier, Burlington, VT (US)

Correspondence Address: EDELL, SHAPIRO & FINNAN, LLC, 1901 RESEARCH BLVD., SUITE 400, ROCKVILLE, MD, 20850, US

(21) Appl. No.: 11/387,882

(22) Filed: Mar. 24, 2006

(51) Int. Cl. G11C 7/02

(52) U.S. Cl. 365/208

(57) ABSTRACT

A semiconductor memory device and method are provided in which leakage current of the memory device is reduced. A sense amplifier is isolated from a memory array that has an anomalous bitline leakage when the memory array is not selected.

### BACKGROUND OF THE INVENTION

FIG. 1 illustrates a sense amplifier 50 in a state-of-the art dynamic random access memory (DRAM) device comprising a complementary pair of bitlines (BL and BL/) 10 and 12 that intersect with wordlines (WLs) 20 and 22. Only two WLs are shown for simplicity. There is a multiplexer circuit 30 and an equalizer circuit 40 that control the connection and isolation of a sense amplifier 50 with respect to the BLs 10 and 12 with WLs 20 and 22. Exemplary memory cells are shown at 60 and 62 at the intersection of the BLs 10 and 12 with WLs 20 and 22.

There are also WLs 70 and 72 on the opposite side of the sense amplifier 50 that intersect with BLs 16 and 18. At the intersection there are memory array cells 80 and 82. The sense amplifier 50 is shared by the memory arrays on both sides. There is a multiplexer circuit 90 and equalizer circuit 95 that control the connection and isolation of the sense amplifier 50 with the memory array on the other side. For purposes of this description, the left side memory array is the “t” side and the right side is the “b” side.

The primary purpose of multiplexer circuits 30 and 90 is to isolate the BLs of the unselected memory array during a sense operation (of the selected memory array) and to allow the sense amplifier internal nodes to be precharged via the BL and /BL nodes. The multiplexer is also used to connect the sense amplifier internal nodes to the bitlines of the selected array for reading from and writing to the memory cell. Multiplexer circuit 30 is controlled by multiplexer control signal MUXb and multiplexer circuit 90 is controlled by multiplexer control signal MUXt. The equalization circuits 40 and 95 are controlled by equalization control signals EQLb and EQLt, respectively. The operation is as follows.

In normal operation when a memory array is unselected, the equalizer circuits 40 and 95 are on, precharging BL and /BL and both multiplexer control signals (MUXt and MUXb) are set to a voltage that is high enough to turn on the multiplexer transistors such that the internal sense amplifier nodes (SA and /SA) are brought to the same potential as BL nodes BL and /BL. When a memory cell is selected in an array on one side of the sense amplifier 50 the equalization circuit transistors on that side are turned off while the multiplexer control signal on that side is boosted to a high enough voltage to permit fast reading and writing of data between the internal sense amplifier nodes (SA and /SA) and the BLs (BL and /BL) and the selected array cell. At the same time the multiplexer control signal for the unselected array is turned off to isolate the unselected array for the duration of the memory access while the equalization circuit of the unselected array remains on. The WL to the selected memory cell is then brought to a voltage that is high enough to turn on the cell access transistor and effectively connect the memory cell capacitor to a bitline (BL or /BL) and after a sufficient time the sense amplifier 50 is turned on to amplify the resulting voltage difference of BL and /BL to a full digital data signal. At the completion of an array access operation the WL is reset back to the unselected potential, the sense amplifier 50 is turned off, and the multiplexer control signals (MUXb and MUXt) and the equalization control signals (EQLb and EQLt) are returned to the precharging condition.

The multiplexer circuits 30 and 90 devices are normally used to isolate BL nodes from internal sense amplifier nodes during sensing but they can also be used to isolate BL nodes from internal sense amplifier nodes at other times for other purposes such as for isolating BL nodes from internal sense amplifier nodes for reducing array leakage due to defects.

In a DRAM device such as that shown in FIG. 1, a (BL-WL) short-circuit condition can result from manufacturing defects. When this occurs, the voltage on the BL associated with the defect is pulled towards the potential of an unselected WL during time periods when that portion of the memory array is unselected. Leakage current supplied to the short-circuit can come from the equalize circuit and/or the internal nodes of the sense amplifier 50. This leakage current is undesirable and adds to the totals current that the memory device draws from the power supply. A way to reduce the undesirable leakage is to disconnect or isolate the defect from the short. If a short-circuit occurs only in one of the two arrays connected to a sense amplifier the multiplexer circuits 30 and 90 may be controlled to isolate the circuits on the side where the short-circuit occurs while the opposite side multiplexer circuit can remain on to maintain the precharged condition of the internal sense amplifier nodes.

Control logic circuitry in a control portion of the DRAM chip supplies isolate control signals to all the memory arrays to control the state of the multiplexer circuits and to isolate BLs from internal sense amplifier nodes for the purpose of blocking defect leakage current during periods that the array is not accessed. FIG. 2 illustrates an example of a conventional multiplexer control circuit shown at reference numeral 32. The multiplexer control circuit 32 comprises NAND gates 33, 34 and 35. The isolate control signals are shown as bISOOFFMUXt and bISOOFFMUXb, where bISOOFFMUXt is input to control circuit 32 for forcing the multiplexer control signal MUXt to the isolating state and bISOOFFMUXb is input to another control circuit of the type shown in FIG. 2 that forces the multiplexer control signal MUXb to the isolating state.

At the beginning and end of each self-refresh cycle, the isolate control signals bISOOFFMUXt and bISOOFFMUXb are dis-asserted and asserted to turn on and off, respectively, the corresponding multiplexer circuit at the beginning and end of each self-refresh cycle for all memory array segments. The isolate control signals bISOOFFMUXt and bISOOFFMUXb must be dis-asserted and asserted because block select control signals BLKSEL and BLKSELi to the multiplexer control circuits do not override the isolate control function. When isolate control signal bISOOFFMUXt is asserted, a voltage is imposed on the transistor 36 that forces MUXt to go low. When the need arises to sense the voltage in memory cells on a side of the sense amplifier in which the multiplexer circuits were isolating, it is necessary to switch them back to an “on” state to allow the sense amplifier to sense voltage difference between BL and /BL. The bISOOFFMUXt is dis-asserted by transitioning to a logic high level and the MUXt is controlled by the BLKSEL and BLKSELi signals. At the end of the access cycle, the multiplexer circuit is turned off to isolate the sense amplifier from the BL by re-asserting bISOOFFMUXt causing MUXt to go low.

There are several disadvantages with this scheme. First, the same isolate control signals are supplied to control the multiplexers in all of the memory array blocks even when only a particular memory array block is accessed. By globalizing this function, more signal lines need to be switched than is necessary. This uses a relatively large amount of switching current that offsets any reduction in the defect leakage current. Also, time must be allocated for entry to and exit from the leakage limiting mode of operation. The additional time requirement degrades array performance and limits the useful application of the globalized isolate control to be applied only during industry standard self-refresh mode.

### SUMMARY OF THE INVENTION

Briefly, a semiconductor memory device and method are provided in which leakage current of the memory device is reduced. A sense amplifier is isolated from a memory array that has an anomalous bitline leakage when the memory array is not selected.

### BRIEF DESCRIPTION OF THE DRAWINGS

FIG. 1 is a block diagram showing a sense amplifier shared by two memory arrays of a conventional memory device.

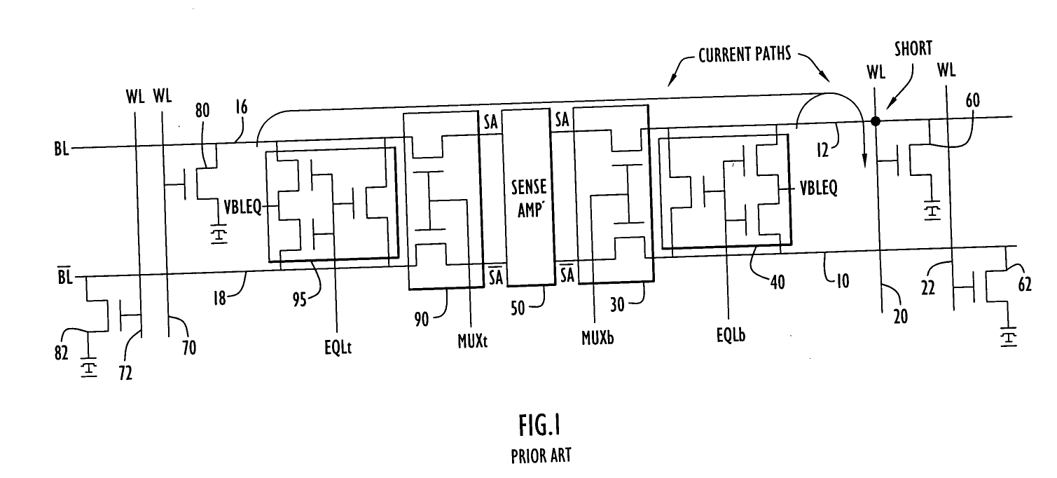

FIG. 2 is a schematic diagram showing a conventional multiplexer control circuit.

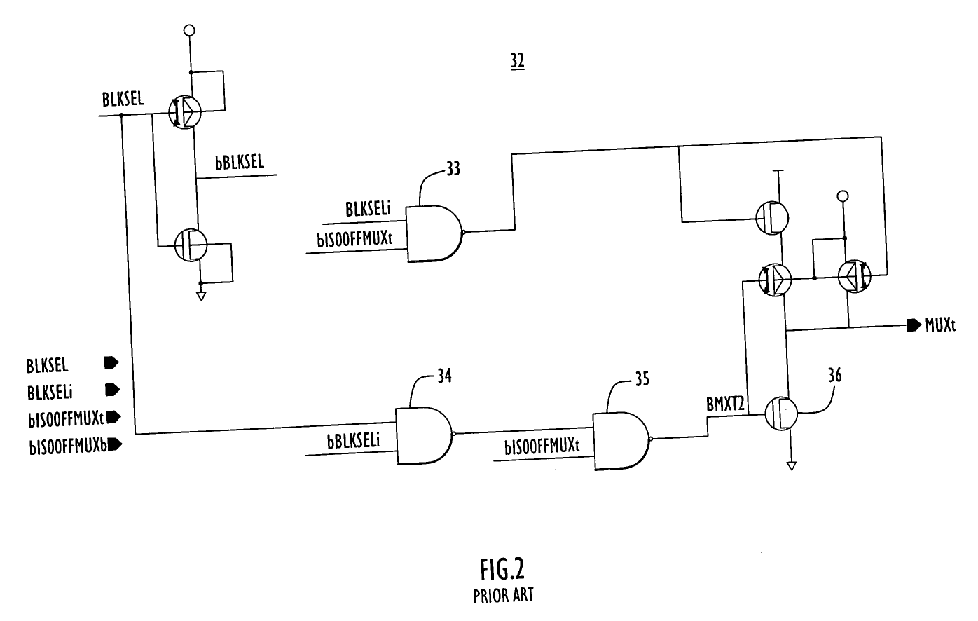

FIG. 3 is a block diagram showing a memory device incorporating the multiplexer control scheme according to one embodiment of the present invention.

FIG. 4 is a schematic diagram showing a multiplexer control circuit according to an embodiment of the present invention.

FIG. 5 is a timing diagram showing a first mode of operation of the multiplexer control circuit according to an embodiment of the present invention.

FIG. 6 is a timing diagram showing a second mode of operation of the multiplexer control circuit according to an embodiment of the present invention.

FIG. 7 is a schematic diagram showing a variation of the multiplexer control circuit shown in FIG. 4, according to another embodiment of the present invention.

FIG. 8 is a timing diagram showing operation of the multiplexer control circuit shown in FIG. 7 according to one embodiment the present invention.

FIG. 9 is a timing diagram showing operation of the multiplexer control circuit shown in FIG. 7 according to another embodiment the present invention.

### DETAILED DESCRIPTION

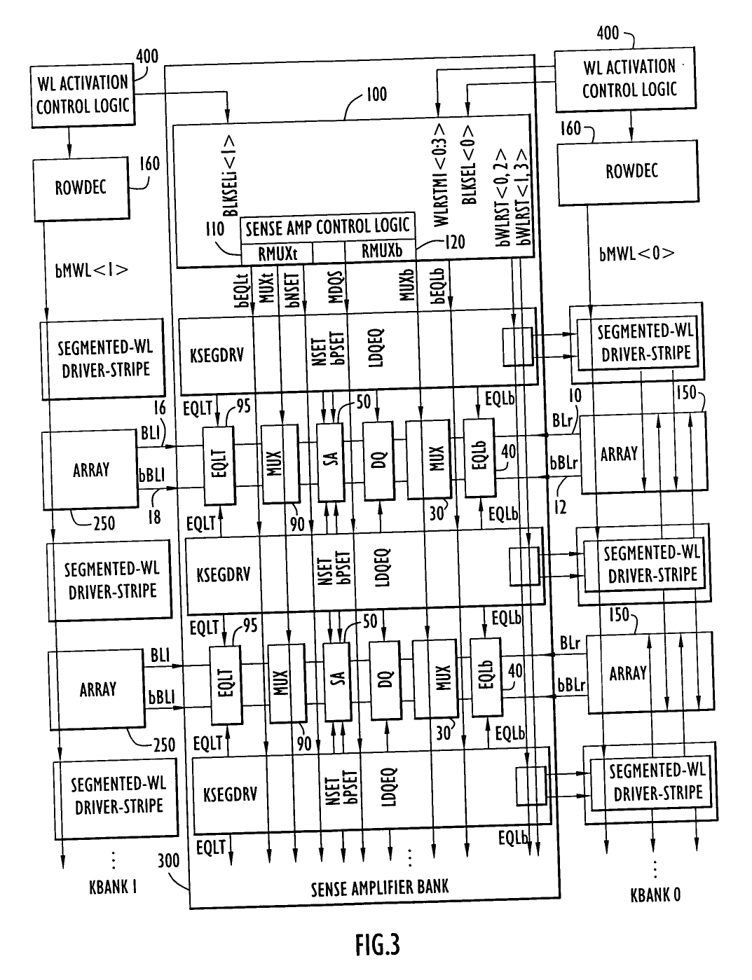

Referring first to FIG. 3, the BL isolation control techniques according to an embodiment of the present invention will be described. There are two multiplexer control circuits RMUXt 110 and RMUXb 120 located in a sense amplifier control logic section 100 of a sense amplifier bank 300. The RMUXt circuit 110 generates the MUXt signal and the RMUXb circuit 120 generates the MUXb signal. The two circuits 110 and 120 are identical, except that the block select signals BLKSEL and BLKSELi are interchanged in their connections to each circuit.

FIG. 3 illustrates a segmented DRAM architecture having multiple banks, KBank0, KBank1, etc, according to one embodiment. In each bank, there are columns of multiple memory arrays. For example, KBank0 has memory arrays 150 and KBank1 has memory arrays 250. Each memory array comprises multiple WLs activated under control of a master WL (e.g., bMWL0 for KBank0) and there are memory cells at the intersection of BLs, such as BLs 10 and 12, with the WLs in each memory array 150 and 250. Access to each memory bank is controlled by a corresponding row decoder (RowDec) 160. The sense amplifier bank 300 is positioned between array banks, with sense amplifiers 50 shared by arrays 150 and 250 on opposite sides. On one side the sense amplifier 50 there is the multiplexer circuit 30 and equalizer circuit 40 associated with array 150 and on the other side of the sense amplifier 50 there is the multiplexer circuit 90 and equalizer circuit 95 associated with array 250. The sense amplifier control logic section 100 resides in the sense amplifier bank 300 and generates the various sense amplifier related control signals as described in the embodiments herein.

The multiplexer control circuits RMUXt 110 and RMUXb 120 control the corresponding multiplexer circuits 90 and 30, respectively, such that the isolation control signals control only non-selected multiplexer output state. That is, the block select signals BLKSEL and BLKSELi automatically override the isolate control signal state and bring the output of the multiplexer to the proper selected state, regardless of its starting state. In addition, dis-assertion of the block select signals BLKSEL and BLKSELi returns control of the multiplexers back to the isolate control signals during non-select time intervals, that is, when the memory array is not being accessed. In one embodiment, the BLKSEL and BLKSELi signals may be generated in the WL activation control logic section 400 along a periphery of an array in the memory device. The block select signals are dependent on which block of the array is to be accessed based on incoming address information. In one embodiment, this is where the logic resides that generates the signals that turn on and off a WL and to control the sense amplifiers that are in a column along the edge of array segments.

The multiplexer control techniques according to the embodiments of the present invention block the bitline short-circuit type of defect leakage current flowing through sense amplifier devices when the memory array having the defect is an unselected state, thereby reducing the current consumption of the memory device. In addition, the isolate control signal does not have to be dis-asserted during array accesses. In one embodiment, the isolate control signals can be DC-fuse configured to operate in normal standby and self-refresh modes without access penalty. Previous multiplexer control schemes only isolate the BLs from the sense amplifier to block leakage current from bitline shorts during self-refresh. More generally, the BL isolation control techniques according to the embodiments described herein may be used to isolate a memory array that has an anomalous bitline leakage that may be due to low resistive path defects (e.g., short-circuits), excessive junction leakage, or other causes. These techniques reduce current in a standby state of the memory device, but more generally they reduce the current consumption of the memory device whenever the memory array or memory bank containing the defect is unselected.

The intelligence to keep track of which memory array segments have an anomalous bitline leakage is contained in manufacturing programs and databases. The memory device is interrogated by test equipment and the test results are stored in computer system files and processed off-line by various analysis programs. These programs create a database file that is accessed when a wafer arrives at a fuse programming tool. The database file tells the fuse programming tool on which memory devices and which array segments on the memory device the isolation feature is to be activated.

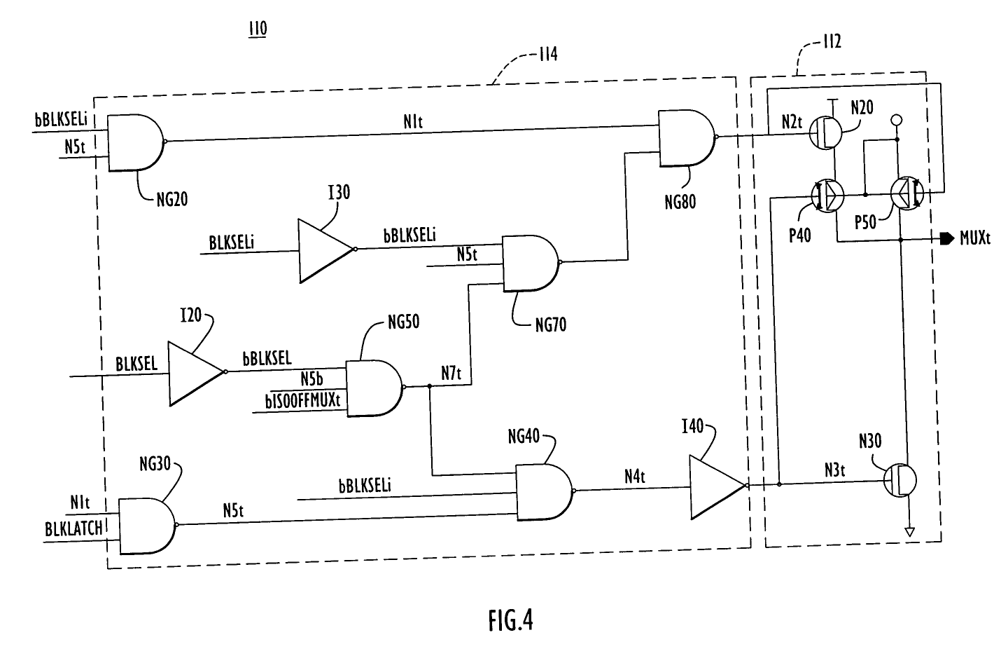

FIG. 4 shows an example of one of the multiplexer control circuits, such as RMUXt 110, according to one embodiment of the invention. Multiplexer control circuit RMUXb 120 is identical, except that the block select signals BLKSEL and BLKSELi are interchanged in their connection to the RMUXt 110 inputs. The multiplexer control circuit RMUXt 110 comprises a transistor network 112 and a digital logic network 114. In the case of multiplexer control circuit RMUXt 110, the inputs are the block select signals BLKSEL,BLKSELi, the isolation control signal bISOOFFMUXt, and node N5b from RMUXb 120. Similarly, the inputs to multiplexer control circuit RMUXb 120 are the block select signals BLKSEL,BLKSELi, the isolation control signal bISOOFFMUXb, and node N5t from RMUXb 110.

In one embodiment, the transistor network 112 comprises N-type field effect transistors (NFETs) N20 and N30, and P-type FETs (PFETs) P40 and P50. The signal at the drain of PFET P40 is the multiplexer control signal MUXt.

In one embodiment, the digital logic network 114 comprises inverters 120 and 130 that produce signals bBLKSEL and bBLKSELi from block signal signals BLKSEL and BLKSELi, respectively. In addition, in one embodiment the digital logic network 114 further comprises NAND gates NG20-NG80. An inverter 140 couples the output of NAND gate NG40 to the gate of NFET N30 in the transistor network 112. The output of NAND gate NG80 is coupled to the gate of NFET N20.

According to the embodiments of the invention, the block select signals BLKSEL and BLKSELi can override the isolate control signals to control the multiplexer state regardless of the previous multiplexer state and the status of the isolate control signals. The multiplexer circuits 30 and 90 are controlled such that the isolation control signals affect only the multiplexers for the non-selected memory arrays. After the block select signals are dis-asserted, the multiplexer control circuit returns the multiplexer circuit to the state defined by the isolate control signal state or to VINT if the isolate control signal is not asserted. Otherwise, the MUXt signal returns to ground if the isolate control signal is asserted. Therefore, instead of using the logic in the ‘spine’ or central logic control region of the chip to generate the control signals which determine when to isolate and not isolate BLs for the purpose of reducing leakage current, the isolate control logic for the multiplexer circuits is embedded in the sense amplifier control logic section of the device and is therefore block selective. Moreover, the multiplexer control circuit automatically overrides the isolate control signal state for all types of array accesses and does not need to make a distinction between a normal selected state and a self-refresh selected state. Consequently, if there is a BL-WL short-circuit (causing a BL leakage current in the sense amplifier) resulting from a defect in a particular memory array, that memory array can also be isolated from the sense amplifier (as opposed to being allowed to remain weakly connected to it).

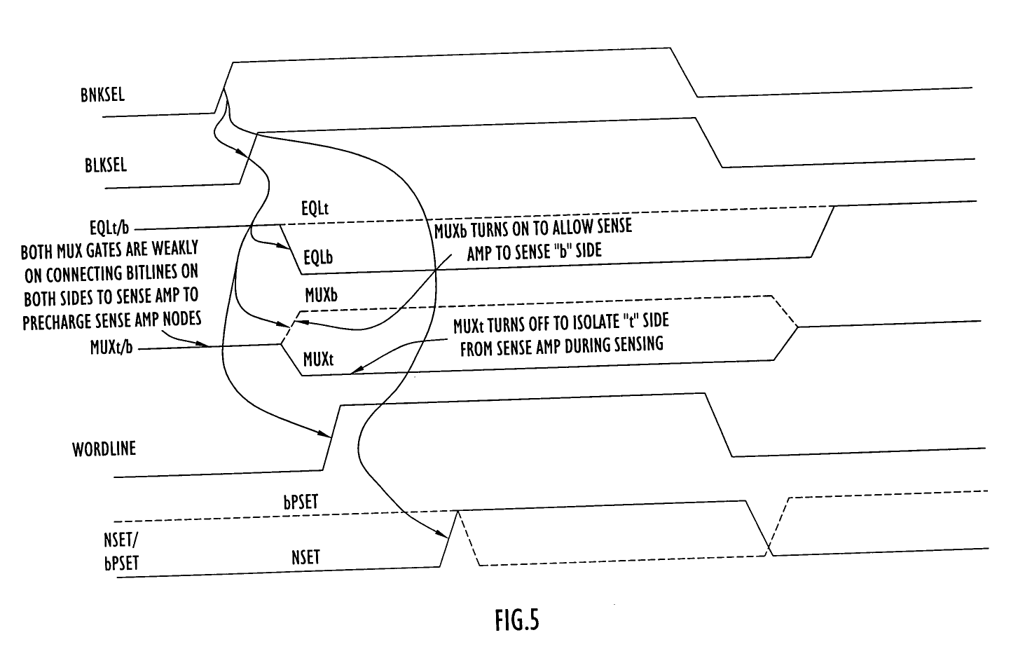

Turning to FIG. 5, with continued reference to FIGS. 3 and 4, operation of the multiplexer control circuits 110 and 120 will be described according to one embodiment. FIG. 5 illustrates timing of signals during “normal” operation when there are no defects in a memory array causing a BL-WL short-circuit and an array selection occurs. Normally, the block latch signal BLKLATCH is low, the isolation control signals bISOOFFMUXt and bISOOFFMUXb are high. The initial state of the block select signals BLKSEL and BLKSELi are low, and both multiplexer control signals MUXt/b are at a VINT level connected to a VINT supply through series connection of NFET N20 and PFET P40. Thus, multiplexer circuits 30 and 90 on both sides of the sense amplifier 50 are weakly on connecting BLs to precharge nodes of sense amplifier 50. Nodes N5t and N5b are at a logic high level.

The bank select signal BNKSEL goes high for a particular bank to activate that bank in the memory device depending on the address to be accessed. Once the address is stable, the BLKSEL (or BLKSELi) signal goes high for a particular block within the selected bank, thereby activating the corresponding multiplexer control circuit for the selected block (also referred to as a selected array segment). Just prior to activating the multiplexer, the equalizer circuit for the side of the sense amplifier that is accessed (sensed), EQLb, turns off while the EQLt remains at a high level to keep the unselected array precharged.

When BLKSEL transitions to a high state, bBLKSEL transitions to a low state, thereby forcing the output of NAND gate NG50 to a high state. Since nodes N5t and bBLKSELi are already at a high state, the output of NAND gate NG50 going high forces the output of NAND gate NG70 and the output of NAND gate NG40 at node N4t to a low state. A low input to NAND gate NG80 forces node N2t high turning PFET P50 off and turning NFET N20 on. A low input to inverter 140 forces node N3t high turning PFET P40 off and turning NFET N30 on. The output signal MUXt is pulled to a low logic level to turn multiplexer circuit 90 off thereby isolating BLs from sense amplifiers on the “t” side of the sense amplifiers. Conversely, multiplexer control circuit 120 for the multiplexer circuit 30 on the opposite “b” side of the sense amplifier outputs control signal MUXb which is pulled to a VPP voltage level strongly connecting the BL's to the sense amplifiers on the “b” side of the sense amplifier.

When BLKSELi transitions to a high state, bBLKSELi transitions to a low state and forces nodes N1t, N4t, and the output of NAND gate NG50 to a high state. Node N3t transitions to a low state turning off NFET N30. Node N2t transitions to a low state turning off NFET N20 and turning on PFET P50. The output MUXt is pulled to a VPP voltage level strongly connecting the BLs to the sense amplifiers on this side of the sense amplifiers. When either BLKSEL or BLKSELi is dis-asserted the reverse occurs and MUXt/b returns to a VINT level through the on states of NFET N20 and PFET P40.

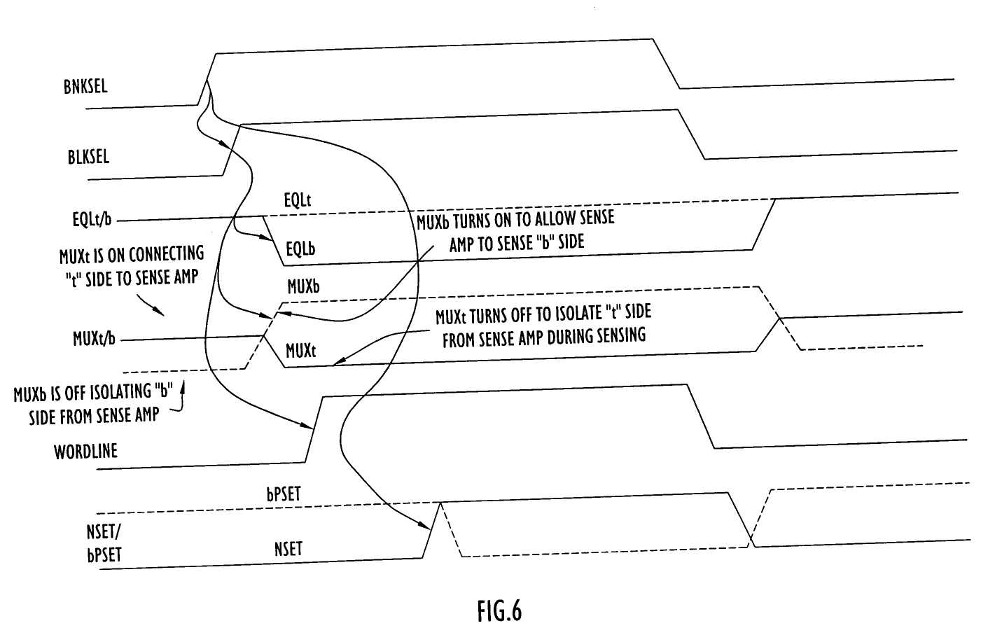

The following describes operation of the multiplexer control circuit 110 under conditions in which the memory device has a BL-WL short-circuit type defect in the array on the “b” side according to an embodiment of the invention. In the embodiment shown in FIG. 6, the “t” side of the sense amplifier 50 starts in a connected state but becomes isolated when the “b” side of the sense amplifier is being sensed. FIG. 6 also shows that the “b” side was being isolated prior to being sensed while the “t” sided was connected when the “b” side is not being sensed.

BLKLATCH is low, bISOOFFMUXb is active low, BLKSEL and BLKSELi are low, the multiplexer control signal MUXb is at a ground potential connected through NFET N30 and the multiplexer control signal MUXt is at VPP or a high level. Nodes N5t and N5b are at a logic high level. The signals bBLKSEL and bISOOFFMUXt are both high maintaining the output of NAND gate NG50 in a low state. The multiplexer control signal that is low, in this example MUXb for the “b” side, disables the multiplexer circuit 30 thereby disconnecting the memory array with the defect from the sense amplifier. This serves to block or isolate the sense amplifier from the memory array side in which the short-circuit type defect is located. Thus, the multiplexer circuit on the side where the short is occurring isolates the sense amplifier 50 from the short whenever that side of the memory array is not selected to access data.

The multiplexer control circuit 110 is activated by asserting BLKSEL or BLKSELi to an active high state, which occurs after the BNKSEL signal has gone high. In this example, when BLKSEL transitions to a high state, bBLKSEL transitions to a low state and forces nodes N1t, N4t, and the output of NAND gate NG50 to a high state. Consequently, node N3t transitions to a low state turning off NFET N30. Node N2t transitions to a low state turning off NFET N20 and turning on PFET P40. When PFET P40 is turned on, the output signal MUXb is pulled to VPP voltage level thereby strongly connecting the BLs to the sense amplifiers 50 on the “b” side. Conversely, the multiplexer control signal MUXt goes low to isolate the “t” side from the sense amplifier 50 as shown in FIG. 6.

On the other hand (though not shown in FIG. 6), when BLKSELi transitions to a high state, bBLKSELi transitions to a low state, but the output of NAND gate NG50 is already at a high state with the node N4t already high and node N3t already low. Under these conditions, MUXb remains at a logic low level continuing to isolate BLs from sense amplifiers on this side and MUXt would transition from a VINT level to a VPP level to strongly connect the “t” side memory array to the sense amplifier. Since the inputs to NAND gate NG70 are all at logic high levels, its output remains at a low level maintaining node N2t at a logic high level. When node N2t is at a high level, PFET P40 is off and NFET N20 is on. Thus, the multiplexer control signal MUXb remains at a logic low level continuing to isolate BLs from sense amplifier on the “b” side. When BLKSELi is dis-asserted the reverse happens and MUXt returns to a VINT level through the on states of PFET P40 and NFET N20. It should be understood that if there is a anomalous bitline leakage on both the “b” side and “t” side arrays of the sense amplifier, then multiplexer circuits on both sides can be controlled so that both “b” and “t” side arrays are isolated from the sense amplifier 50 when the memory arrays are unselected.

FIG. 6 shows at the end of an access to a selected array MUXb returns to a ground level and MUXt returns to a VINT level. At this time the BLs of the selected array and internal sense amplifier nodes are starting to be equalized and precharged. The precharge of the internal sense amplifier nodes in this embodiment occurs through multiplexer circuit 90 with the multiplexer control signal MUXt in a weakly on condition. Under this condition the internal sense amplifier nodes are not precharged as quickly as when both multiplexer control signals, MUXt and MUXb, are both on, as in normal operation.

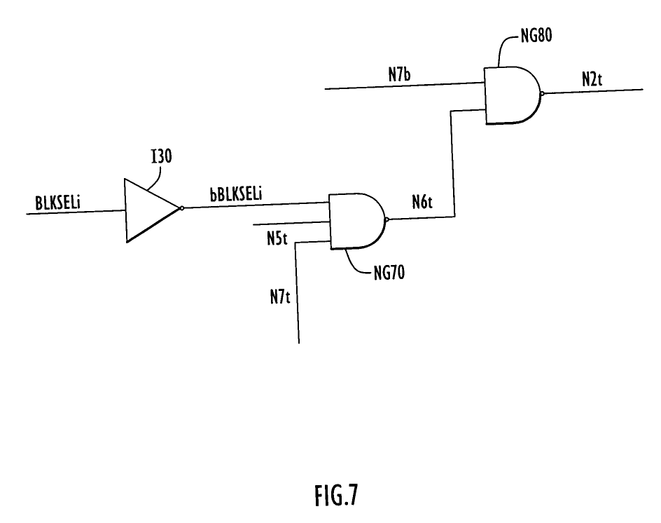

FIG. 7 shows a modification to the multiplexer control circuit 110 shown in FIG. 4 according to another embodiment of the invention, in which node N7b from RMUXb 120 also connects as an input to RMUXt 110. In this embodiment, the NAND gate NG70 receives as input the output of inverter 130, node N5t and node N7t corresponding to the output of NAND gate NG50 (FIG. 4). In this embodiment, the output N6t of NAND gate NG70 is coupled to NAND gate NG80. Node N7b is the other input to NAND gate NG80. The rest of the multiplexer control circuit 110 (not shown in FIG. 7) is the same as that shown in FIG. 4.

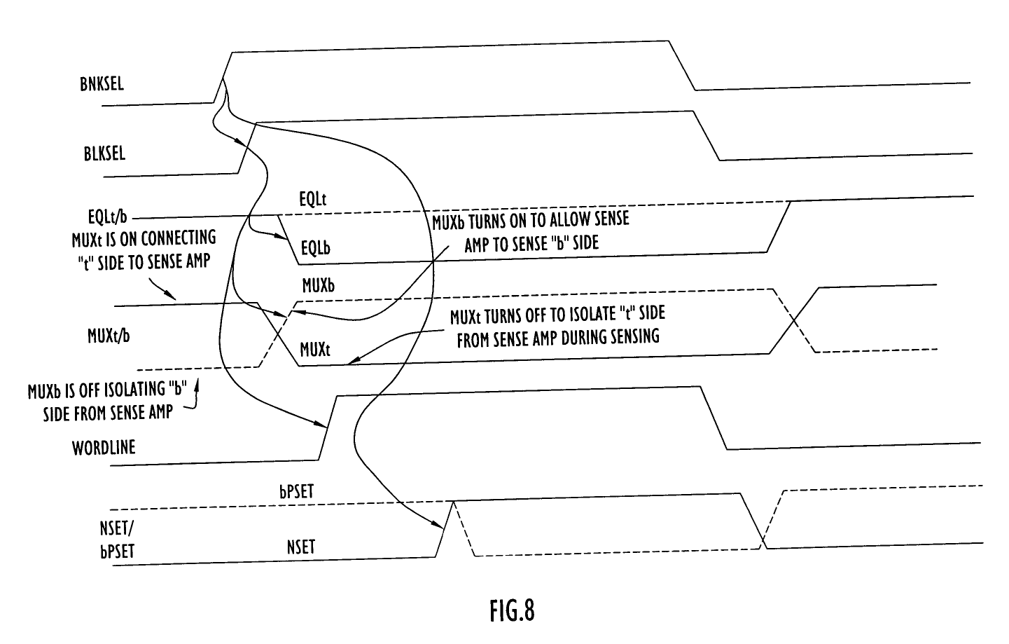

FIG. 8 shows one embodiment of an operation of the modified multiplexer control circuit 110 as depicted in the embodiment on FIG. 7. The operation is similar to that shown in FIG. 6, except that when bISOOFFMUXb is active low, MUXt starts from a VPP level and returns to a VPP level instead of to a VINT level. The higher level of MUXt when the array is unselected causes the multiplexer circuit to be turned on strongly and allows the internal sense amplifier nodes to be equalized and precharged more quickly by the BLs on the “t” side after the array access has ended.

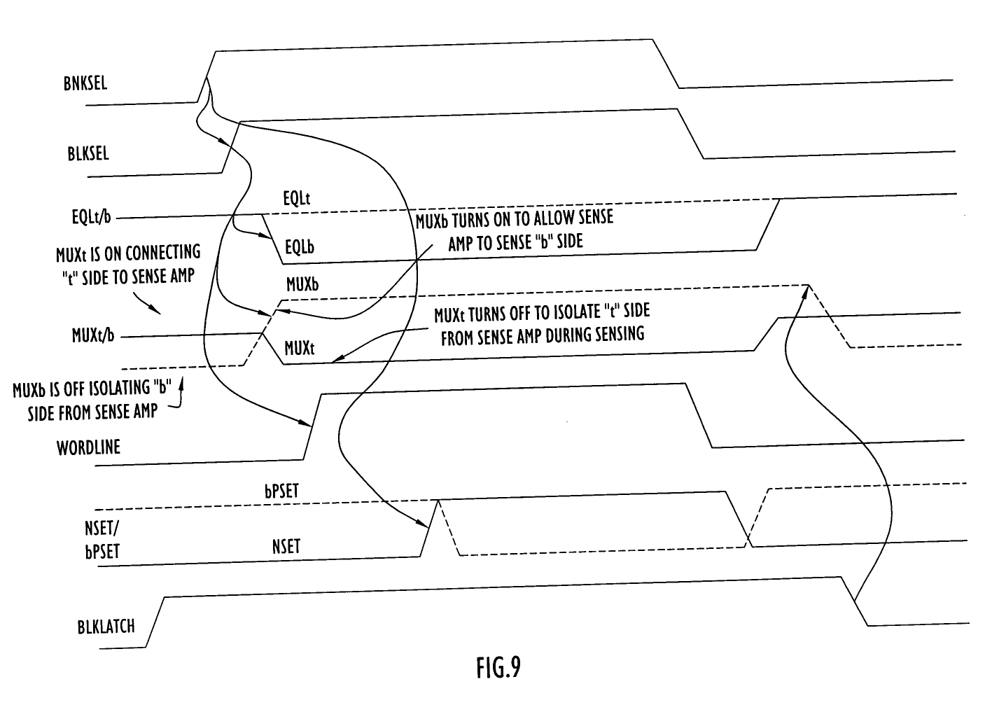

FIG. 9 illustrates another embodiment of an operation of the modified multiplexer control circuit 110 as depicted in the embodiment of FIG. 7. This operation is similar to that shown in FIG. 6 except that the fall of the MUXb control signal is delayed at the end of array cycle when ISOOFFMUXb is active low. The extension of the time that MUXb is at a VPP level after the block select signal has gone low (the time interval for the accessing or sensing the “b” side is completed, also referred to as the “selection period” for the “b” side) allows the multiplexer circuit on that side of the sense amplifier to be strongly on when the BLs on the selected side are equalized and precharged. This allows the internal nodes of the sense amplifier to be equalized and precharged more quickly after the array access has ended. The signal BLKLATCH is activated before or during the array access cycle and the cross-coupling of nodes N5 between the multiplexer control circuits RMUXt 10 and RMUXb 120 allows the MUXt and MUXb control signal states to become latched such that even when BLKSEL or BLKSELi is dis-asserted the MUXt and MUXb selected states do not change. When the array cycle ends the BLKLATCH signal goes low after a predetermined delay, unlatching the RMUXt and RMUXb circuits and allowing the multiplexer control signals MUXt and MUXb to resume their unselected states. In other words, in one embodiment the RMUXt and RMUXb multiplexer control circuits may be connected together and each is responsive to a latch signal (BLKLATCH) that causes the first and second control circuits to remain in a selected state after the selection period has ended.

A further advantage of this embodiment is that the BLKLATCH signal can be used in self-refresh mode to prevent the multiplexer control circuits RMUXt and RMUXb from switching between selected and unselected states. This allows a reduction in switching current during periods of self-refresh cycles when array address sequencing is not random and can be designed to proceed linearly through the address range of an array segment before crossing the boundary to the next array segment. The BLKLATCH can remain on while refreshing within the array segment and can turn off when switching between array segments to provide the reduction in switching current.

The system and methods described herein may be embodied in other specific forms without departing from the spirit or essential characteristics thereof. The foregoing embodiments are therefore to be considered in all respects illustrative and not meant to be limiting.

What is claimed is:

1. A method for reducing leakage current of a memory device, comprising isolating a sense amplifier from a memory array that has an anomalous bitline leakage when said memory bank containing the memory array is not selected.

2. The method of claim 1, wherein isolating comprises disabling a multiplexer circuit coupled between the sense amplifier and the memory array so that the multiplexer circuit disconnects the memory array from the sense amplifier.

3. The method of claim 2, and further comprising connecting said sense amplifier to said memory array when said memory array is selected for access, and subsequently isolating the sense amplifier from the memory array after the access is completed.

4. A method for reducing leakage current of a memory device in which a sense amplifier is shared by first and second memory arrays on opposite sides of the sense amplifier, comprising isolating the first memory array from the sense amplifier when the first memory array is not selected and when the first memory array has a anomalous bitline leakage.

5. The method of claim 4, wherein when neither of the first and second memory arrays has an anomalous bitline leakage, connecting the sense amplifier to the first memory array when the first memory array is selected and isolating the second memory array from the sense amplifier.

6. The method of claim 5, and further comprising isolating said sense amplifier from said first memory array after access to said first memory array is completed.

7. The method of claim 4, wherein isolating comprises disabling a multiplexer circuit coupled between the sense amplifier and the first memory array so that the multiplexer circuit disconnects the first memory array from the sense amplifier.

8. The method of claim 4, wherein when the second memory array has an anomalous bitline leakage, isolating the second memory array from the sense amplifier when the second memory array is not selected.

9. The method of claim 4, and further comprising connecting said sense amplifier to said second memory array when said second memory array is unselected to allow internal nodes of the sense amplifier to be precharged and equalized more quickly after array access has ended.

10. The method of claim 4, and further comprising connecting the first memory array to the sense amplifier when the first memory array is selected and maintaining connection of said first memory array to the sense amplifier beyond a time interval for accessing said first memory array in order to allow internal nodes of the sense amplifier to be precharged and equalized more quickly after array access has ended.

11. A semiconductor memory device, comprising:
a. a memory array comprising memory cells;
b. a sense amplifier;
c. a multiplexer between said sense amplifier and said memory array that selectively connects the sense amplifier to the memory array; and
d. a control circuit coupled to said multiplexer that controls the multiplexer to isolate said memory array from said sense amplifier when said memory array is unselected and has an anomalous bitline leakage.

12. The memory device of claim 11, wherein said control circuit disables said multiplexer so that the multiplexer disconnects the memory array from the sense amplifier in order to isolate said memory array from the sense amplifier.

13. The memory device of claim 11, wherein said control circuit is responsive to determining that said memory array is not selected to maintain said sense amplifier isolated from said memory array.

14. The memory device of claim 11, wherein said control circuit is responsive to a select signal indicating that said memory array is to be accessed and controls the multiplexer to connect said sense amplifier to said memory array, and subsequently controls the multiplexer to isolate the memory array from the sense amplifier after the memory array access is completed.

15. A semiconductor memory device, comprising:
a. a first memory array comprising memory cells;
b. a second memory array comprising memory cells;
c. a sense amplifier shared by said first and second memory arrays;
d. a first multiplexer between said sense amplifier and said first memory array that selectively connects the sense amplifier to the first memory array;
e. a second multiplexer between said sense amplifier and said second memory array that selectively connects said sense amplifier to said second memory array;
f. a first control circuit coupled to said first multiplexer that controls the first multiplexer to isolate the sense amplifier from said first memory array of the memory device when said first memory array contains an anomalous bitline leakage and said first memory array is unselected; and
g. a second control circuit coupled to said second multiplexer that controls the second multiplexer to isolate the sense amplifier from said second memory array when said second memory array contains an anomalous bitline leakage and said second memory is unselected.

16. The memory device of claim 15, wherein said first control circuit disables said first multiplexer circuit to disconnect the sense amplifier from the first memory array in order to isolate said first memory array.

17. The memory device of claim 15, wherein said first and second control circuits receive a select signal indicating whether said first memory array or said second memory array is to be accessed, and when said select signal indicates that said first memory array is to be accessed, said first control circuit connects said sense amplifier to said first memory array and said second control circuit connects to ground to isolate said second memory array from said sense amplifier.

18. The memory device of claim 17, wherein when said select signal indicates that said second memory array is to be accessed, said second control circuit connects said sense amplifier to said second memory array and said first control circuit stays connected to ground to continue to isolate said first memory array from said sense amplifier.

19. The memory device of claim 15, wherein the first control circuit and second control circuit are connected together, wherein the first and second control circuits are each responsive to a latch signal that causes the first and second control circuits to remain in the selected state after the selection period has ended.

20. A semiconductor memory device, comprising:
a. an array of memory cells at intersections of wordlines and bitlines;
b. means for sensing charge from said memory cells on said bitlines;
c. means for connecting said means for sensing to said bitlines; and
d. means for controlling said means for connecting to isolate said array from said means for sensing in when said array contains an anomalous bitline leakage and said array is unselected.

21. The memory device of claim 20, wherein said means for connecting disconnects said array from said means for sensing in order to isolate said means for sensing from said bitlines.

22. The memory device of claim 20, wherein said means for controlling is responsive to determining that said array is not selected to maintain said means for selecting isolated from said array.

23. The memory device of claim 20, wherein said means for controlling is responsive to a signal indicating that said array is to be accessed and generates a control signal that causes said means for connecting to connect said means for sensing to said bitlines, and subsequently generates a control signal that causes the means for connecting to isolate said means for sensing from said array.
